(19) United States
(12) Patent Application Publication
(10) Pub. No.: US 2023/0395377 A1
(43) Pub. Date: Dec. 7, 2023

(54) PREPARATION METHOD FOR AMORPHOUS SILICON INTEGRATED WITH TUNNELING OXIDE LAYER

(71) Applicant: Popsolar Technology (Taixing) Co., Ltd, Taixing (CN)

(72) Inventor: Wenkai OU, Taixing (CN)

(21) Appl. No.: 18/446,505

(22) Filed: Aug. 9, 2023

Related U.S. Application Data
(63) Continuation of application No. PCT/CN2021/096255, filed on May 27, 2021.

(30) Foreign Application Priority Data
Apr. 8, 2021 (CN) 2021103792553

(51) Int. Cl. H01L 21/02; C23C 16/24

(52) U.S. Cl. CPC H01L 21/0262; H01L 21/02532; H01L 21/02488; H01L 21/02381; H01L 21/02236; H01L 21/02164; C23C 16/24

(57) ABSTRACT

A preparation method for amorphous silicon integrated with a tunneling oxide layer is provided, i.e., growth of an ultra-thin tunneling oxide layer and growth of the amorphous silicon are performed in a same process equipment without Q-time, such that process steps can be reduced, additional wafer loading and unloading processes are not involved, and scratch and pollution risks are not increased. Compared with an oxidation and amorphous silicon growth with a separation mode, the preparation method has a more excellent passivation result.

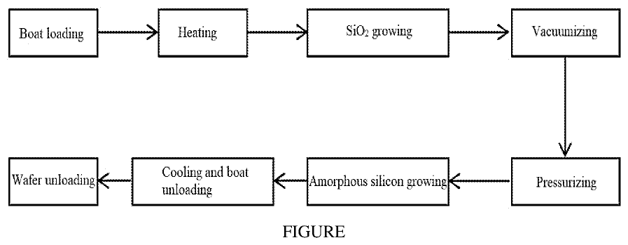

### TECHNICAL FIELD

The disclosure relates to the technical field of solar cells, particularly to a preparation method for amorphous silicon integrated with a tunneling oxide layer.

### BACKGROUND

Photovoltaic power generation wants to become a universal energy source, which is of great significance to achieve grid parity access. Therefore, it is of great need to improve a conversion efficiency of solar cells, thereby to some extent reducing power cost. For a highly efficient solar cell, the recombination loss at the contact area is one of the important factors limiting the efficiency improvement.

A conventional method to address the above impact factor is to use local contact that reduces an effective contact area between a silicon base and a metal electrode, and uncontacted areas are blocked by a passivation layer or other masking layers, such as a passivated emitter and rear cell (PERC), a passivated emitter and rear locally-diffused cell (PERL), and other cells. However, an ohmic loss caused by a lateral transmission of charge carriers of the above cells is a key of cell design.

Another solution to reduce the recombination loss of the contact area is to make a selective passivation contact consisting of materials placed between a silicon base and a metal electrode, effectively inhibiting recombination of charge carriers through defects at a surface of the silicon base, while also functioning as contact. Due to the low recombination loss of such passivation contact, it can be used as a passivation layer on the whole surface, thereby avoiding using a separate passivation layer to contact with a local metal. The selective passivation contact has the potential to simplify solar cell manufacturing process and to improve the efficiency of the solar cells. An N-type tunneling oxide passivated contact (N-TOPCon) solar cell is prepared based on the selective passivation contact theory, a structure of which includes an ultra-thin oxide layer (also referred to an electron tunneling layer) and a phosphorus-doped polysilicon layer; and the structure of the N-TOPCon solar cell can also referred to SiOₓ/doped-poly Si.

The TOPCon solar cells are also different in process routing due to some different equipment and manufacturing processes. Process difficulties of industrial TOPCon solar cells are particularly important in a balance of yield, productivity, efficiency and cost. Therefore, whether the industry can take advantages in technology and cost in the future is determined on the design of the process routing.

### SUMMARY

In view of the above impact factors, the disclosure provides a preparation method for amorphous silicon integrated with a tunneling oxide layer to overcome the deficiencies in the related art.

In order to achieve the above objective, the disclosure provides the following technical solutions:

A preparation method for amorphous silicon integrated with a tunneling oxide layer includes the following steps:
step 1 of boat loading, including: loading a silicon wafer subjected to surface polishing into a boat, pushing the boat into a furnace tube, and introducing nitrogen (N₂) during the boat loading; after the boat loading is completed, stopping introducing the N₂, and then vacuumizing the furnace tube, and keeping a vacuum degree of the furnace tube at a range of 100 Torricelli (Torr) to 700 Torr;
step 2 of oxidation, including: keeping a pressure of the furnace tube stable, introducing oxygen (O₂) into the furnace tube after heating the furnace tube to a stable temperature, and then growing silicon oxide (SiO₂); in which the stable temperature of the furnace tube in the step 2 is in a range of 550 degrees Celsius (° C.) to 620° C., a flow range of introducing the O₂ is in a range of 5 standard litter per minute (slm) to 30 slm, and a time of introducing the O₂ is in a range of 5 minutes (min) to 30 min;
step 3 of vacuumizing, including: after the oxidation is completed, turning on a valve of the furnace tube to vacuumize to make the vacuum degree of the furnace tube below 1,000 milliTorr (mTorr), i.e., a vacuum state;
step 4 of pressurizing (i.e., back pressure), including: introducing N₂ to improve the pressure of the furnace tube and maintaining the improved pressure for a period of time;
step 5 of amorphous silicon growing, including: introducing silicon hydride (SiH₄) to grow the amorphous silicon under a stable temperature and a stable pressure; in which the stable temperature in the step 5 is in a range of 550° C. to 600° C., a flow range of introducing the SiH₄ is in a range of 80 standard cubic centimeter per minute (sccm) to 1,000 sccm, the stable pressure in the step 5 is in a range of 250 mTorr to 600 mTorr, and a time of introducing the SiH₄ is in a range of 10 min to 150 min;
step 6, introducing N₂ into the furnace tube and discharging residual SiH₄ in the furnace tube;
step 7 of cooling and boat unloading, including: breaking the vacuum state and removing the boat from the furnace tube after the temperature of the furnace tube is cooled; and
step 8 of wafer unloading, including: removing the silicon wafer from the boat.

In an embodiment, in the step 1, an internal temperature of the furnace tube is in a range of 450° C. to 600° C., and a flow range of introducing the N₂ is in a range of 1 slm to 30 slm.

In an embodiment, in the step 2, the stable temperature of the furnace tube is in a range of 560° C. to 600° C.

In an embodiment, in the step 2, the flow range of introducing the O₂ is in a range of 10 slm to 20 slm, and the time of introducing the O₂ is in a range of 8 min to 15 min.

In an embodiment, the step 3 includes: making the vacuum degree of the furnace tube less than 100 mTorr by the vacuumizing.

In an embodiment, in the step 4, a flow range of introducing the N₂ is in a range of 100 sccm to 10,000 sccm, the improved pressure is in a range of 250 mTorr to 1,000 mTorr, and the period of time is in a range of 0.5 min to 10 min.

In an embodiment, in the step 4, a flow range of introducing the N₂ is in a range of 200 sccm to 1,000 sccm, the improved pressure is in a range of 250 mTorr to 600 mTorr, and the period of time is in a range of 0.5 min to 5 min.

In an embodiment, in the step 5, the flow range of introducing the SiH₄ is in a range of 200 sccm to 500 sccm, the stable pressure is in a range of 300 mTorr to 500 mTorr, and the time of introducing the SiH₄ is in a range of 20 min to 60 min.

In an embodiment, in the step 7, the temperature of the furnace tube is cooled to a range of 400° C. to 550° C.

Beneficial effects of the disclosure are as follows.

(1) The disclosure uses a manner of the amorphous silicon growing integrated with the ultra-thin oxide layer. Namely, the growth of the ultra-thin tunneling oxide layer and the growth of the amorphous silicon are performed in a same process equipment, thereby realizing no Q-time (referred to a waiting time between one step track out to next step track in), and then reducing process steps.

(2) The disclosure uses the manner of the amorphous silicon growing integrated with the ultra-thin oxide layer, which does not involve additional wafer loading and unloading processes, does not increase risks of scratch and pollution, and has a more excellent passivation result than an oxidation and amorphous silicon growth with a separation mode.

### BRIEF DESCRIPTION OF DRAWING

FIGURE illustrates a flowchart of a preparation method for amorphous silicon integrated with a tunneling oxide layer according to the disclosure.

### DETAILED DESCRIPTION OF EMBODIMENTS

In order to make objectives, technical solutions, and advantages of the disclosure much clearer, the disclosure will be described below with reference to attached drawings and embodiments. It should be understood that the embodiments described herein are merely used to explain the disclosure, and are not intended to limit the disclosure. Based on the embodiments provided in the disclosure, all of other embodiments obtained by those skilled in the related art without creative efforts shall fall within the scope of the protection of the disclosure.

Reference throughout the disclosure to “an embodiment” means that a specific feature, structure, or characteristic described in connection with the embodiment may be included in at least one embodiment of the disclosure. Those skilled in the related art explicitly and implicitly understand that the embodiments described in the disclosure may be combined with other embodiments without conflict.

Unless otherwise defined, technical terms or scientific terms involved in the disclosure should be those commonly understood by those skilled in the related art to which the disclosure belongs. The terms such as “a”, “an”, “a kind”, “the” and the like do not denote a quantity limitation, and may represent singular or plural. The terms “including”, “containing”, “possessing”, and any variations thereof involved in the disclosure are intended to cover non-exclusive inclusion. Similarly, the terms, such as “connection”, “connecting to”, “coupled”, and the like involved in the disclosure, are not limited to physical or mechanical connections, but may include electrical connections, whether direct or indirect. In the disclosure, “a plurality of” means two or more. The “and/or” describes an association relationship of the associated objectives, indicating that there may be three relationships. For example, “A and/or B” may indicate that A exists alone, A and B exist at the same time, and B exists alone. The terms, such as “first”, “second”, “third”, and the like involved in the disclosure, are merely used to distinguish similar objectives, and not used to represent a specific order for the objectives.

### Embodiment 1

A preparation method for amorphous silicon integrated with a tunneling oxide layer includes the following steps 1 to 8.

Step 1, boat loading, including: a silicon wafer subjected to surface polishing is loaded into a boat (i.e., a quartz boat), the boat is pushed into a furnace tube, and nitrogen (N₂) is introduced during the boat loading, an internal temperature of the furnace tube is 450 degrees Celsius (° C.), a flow range of introducing the N₂ is in a range of 1 standard litter per minute (slm) to 30 slm, thereby forming a positive pressure within the furnace tube and preventing external particles from entering the furnace tube and resulting in pollution. After the boat loading is completed, the N₂ is stopped introducing, and then the furnace tube is vacuumized, and a vacuum degree of the furnace tube is kept at 100 Torricelli (Torr) stably.

Step 2, oxidation, including: a pressure (i.e., vacuum degree) of the furnace tube is kept stable, the furnace tube is heated to a stable temperature of 560° C., oxygen (O₂) is introduced into the furnace tube after heating the furnace tube to the stable temperature, and then silicon oxide (SiO₂) grows. A flow range of introducing the O₂ is 10 slm, and a time of introducing the O₂ is 10 minutes (min).

Step 3, vacuumizing, including: after the oxidation is completed, a valve of the furnace tube is turned on to vacuumize to keep the vacuum degree of the furnace tube below 100 milliTorr (mTorr), i.e., a vacuum state.

Step 4, pressurizing, including: N₂ is introduced to improve the pressure of the furnace tube (i.e., back pressure) for a period of time. A flow range of introducing the N₂ is 200 standard cubic centimeters per minute (sccm), the improved pressure is 250 mTorr, and the period of time is 3 min.

Step 5, amorphous silicon growing, including: silicon hydride (SiH₄) is introduced to grow the amorphous silicon under a stable temperature and a stable pressure. A flow range of introducing the SiH₄ is 200 sccm, the stable pressure in the step 5 is 300 mTorr, and a time of introducing the SiH₄ is 40 min.

Step 6, N₂ is introduced into the furnace tube and residual SiH₄ in the furnace tube is discharged.

Step 7, cooling and boat unloading, including: the vacuum state is broken and the boat is removed from the furnace tube after the temperature of the furnace tube is cooled to 400° C.

Step 8, wafer unloading, including: the silicon wafer is removed from the quartz boat.

### Embodiment 2

A preparation method for amorphous silicon integrated with a tunneling oxide layer includes the following steps 1 to 8.

Step 1, boat loading, including: a silicon wafer subjected to surface polishing is loaded into a quartz boat, the quartz boat is pushed into a furnace tube, and N₂ is introduced during the boat loading, an internal temperature of the furnace tube is 600° C., a flow range of introducing the N₂ is 20 slm to discharge air within the furnace tube, thereby forming a positive pressure in the furnace tube. After the boat loading is completed, the N₂ is stopped introducing, and then the furnace tube is vacuumized, and a vacuum degree of the furnace tube is kept at 200 Torr stably.

Step 2, oxidation, including: a pressure of the furnace tube is kept stable, the furnace tube is heated to a stable temperature, and then O₂ is introduced into the furnace tube, followed by growing SiO₂. The stable temperature of the furnace tube in the step 2 is 620° C., a flow range of introducing the O₂ is 30 slm, and a time of introducing the O₂ is 5 min.

Step 3, vacuumizing, including: after the oxidation is completed, a valve of the furnace tube is turned on to vacuumize to keep the vacuum degree of the furnace tube below 1,000 mTorr, i.e., a vacuum state.

Step 4, pressurizing, including: N₂ is introduced to improve the pressure of the furnace tube for a period of time. A flow range of introducing the N₂ is 10,000 sccm, the improved pressure is 1,000 mTorr, and the period of time is 1 min.

Step 5, amorphous silicon growing, including: SiH₄ is introduced to grow the amorphous silicon under a stable temperature and a stable pressure. A flow range of introducing the SiH₄ is 1,000 sccm, the stable pressure in the step 5 is 400 mTorr, and a time of introducing the SiH₄ is 10 min.

Step 6, N₂ is introduced into the furnace tube and residual SiH₄ in the furnace tube is discharged.

Step 7, cooling and boat unloading, including: the vacuum state is broken and the quartz boat is removed from the furnace tube after the temperature of the furnace tube is cooled to 450° C.

Step 8, wafer unloading, including: the silicon wafer is removed from the quartz boat.

### Embodiment 3

A preparation method for amorphous silicon integrated with a tunneling oxide layer includes the following steps 1 to 8.

Step 1, boat loading, including: a silicon wafer subjected to surface polishing is loaded into a quartz boat, the quartz boat is pushed into a furnace tube, and N₂ is introduced during the boat loading, an internal temperature of the furnace tube is 500° C., a flow range of introducing the N₂ is 30 slm to discharge air within the furnace tube, thereby forming a positive pressure in the furnace tube. After the boat loading is completed, the N₂ is stopped introducing, and then the furnace tube is vacuumized, and a vacuum degree of the furnace tube is kept at 500 Torr stably.

Step 2, oxidation, including: a pressure of the furnace tube is kept stable, the furnace tube is heated to a stable temperature, and then O₂ is introduced into the furnace tube, followed by growing SiO₂. The stable temperature of the furnace tube in the step 2 is 600° C., a flow range of introducing the O₂ is 15 slm, and a time of introducing the O₂ is 15 min.

Step 3, vacuumizing, including: after the oxidation is completed, a valve of the furnace tube is turned on to vacuumize to keep the vacuum degree of the furnace tube below 100 mTorr, i.e., a vacuum state.

Step 4, pressurizing, including: N₂ is introduced to improve the pressure of the furnace tube for a period of time. A flow range of introducing the N₂ is 1,000 sccm, the improved pressure is 600 mTorr, and the period of time is 1 min.

Step 5, amorphous silicon growing, including: SiH₄ is introduced to grow the amorphous silicon under a stable temperature and a stable pressure. A flow range of introducing the SiH₄ is 500 sccm, the stable pressure in the step 5 is 500 mTorr, and a time of introducing the SiH₄ is 30 min.

Step 6, N₂ is introduced into the furnace tube and residual SiH₄ in the furnace tube is discharged.

Step 7, cooling and boat unloading, including: the vacuum state is broken and the quartz boat is removed from the furnace tube after the temperature of the furnace tube is cooled to 550° C.

Step 8, wafer unloading, including: the silicon wafer is removed from the quartz boat.

### Embodiment 4

A preparation method for amorphous silicon integrated with a tunneling oxide layer includes the following steps 1 to 8.

Step 1, boat loading, including: a silicon wafer subjected to surface polishing is loaded into a quartz boat, the quartz boat is pushed into a furnace tube, and N₂ is introduced during the boat loading, an internal temperature of the furnace tube is 450° C., a flow range of introducing the N₂ is 20 slm to discharge air within the furnace tube, thereby forming a positive pressure in the furnace tube. After the boat loading is completed, the N₂ is stopped introducing, and then the furnace tube is vacuumized, and a vacuum degree of the furnace tube is kept at 700 Torr stably.

Step 2, oxidation, including: a pressure of the furnace tube is kept stable, the furnace tube is heated to a stable temperature, and then O₂ is introduced into the furnace tube, followed by growing SiO₂. The stable temperature of the furnace tube in the step 2 is 550° C., a flow range of introducing the O₂ is 5 slm, and a time of introducing the O₂ is 30 min.

Step 3, vacuumizing, including: after the oxidation is completed, a valve of the furnace tube is turned on to vacuumize to keep the vacuum degree of the furnace tube below 100 mTorr, i.e., a vacuum state.

Step 4, pressurizing, including: N₂ is introduced to improve the pressure of the furnace tube for a period of time. A flow range of introducing the N₂ is 100 sccm, the improved pressure is 250 mTorr, and the period of time is 5 min.

Step 5, amorphous silicon growing, including: SiH₄ is introduced to grow the amorphous silicon under a stable temperature and a stable pressure. A flow range of introducing the SiH₄ is 80 sccm, the stable pressure in the step 5 is 250 mTorr, and a time of introducing the SiH₄ is 150 min.

Step 6, N₂ is introduced into the furnace tube and residual SiH₄ in the furnace tube is discharged.

Step 7, cooling and boat unloading, including: the vacuum state is broken and the quartz boat is removed from the furnace tube after the temperature of the furnace tube is cooled to 400° C.

Step 8, wafer unloading, including: the silicon wafer is removed from the quartz boat.

### Embodiment 5

A contact quality in a crystalline silicon cell can be characterized by J₀ (referred to a current density) and a picoliter (PL) value.

A monitor wafer uses an N-type polished wafer, a back surface of which completes an oxidation and an amorphous silicon growing process (using the preparation method for amorphous silicon integrated with the tunneling oxide layer as described in the embodiment 1), and then a double-sided phosphorus expansion is performed on the monitor wafer, a cleaning machine is used to remove generated double-sided phosphor silicate glass (PSG), i.e., a silicon oxide layer with high phosphorus concentration during preparing the crystalline silicon cell, followed by coating SiNx films on the double sides, and finally, a WCT 120 (referred to a minority carrier lifetime testing machine) and a PL machine are respectively used to test the J₀ and the PL value after sintering the monitor wafer.

An illustrated manufacturing process is as follows.

1. A silicon wafer (such as CZSi) is prepared by a single throw N-type Czochralski (CZ) method with a thickness of 175 micrometers (m) and a resistivity of 1-3 ohm·cm (Q·cm).

2. The silicon wafer is placed into a polishing cleaning machine, the surface of the silicon wafer is polished by using a nitric acid (HNO₃)/hydrofluoric acid (HF) mixed solution, and a reflectivity of the processed silicon wafer is about 30-40%.

3. The silicon wafer subjected to the surface polishing treatment is placed in a quartz boat, and then growing a tunneling oxide layer and amorphous silicon is performed by the preparation method according to the disclosure (specifically as described in the embodiment 1).

4. After the tunneling oxide layer and the amorphous silicon grow, the silicon wafer is placed into a phosphorus diffusion device for phosphorus doping treatment. In the embodiment of the disclosure, a conventional phosphorus doping method in the related art is used, a temperature for the phosphorus doping is 790° C., the introduced phosphorus comes from phosphorus oxychloride (POCl₃), an amount of which is in a range of 800 sccm to 1,000 sccm and an introduction time of which is in a range of 20 min to 25 min.

5. After the phosphorus is diffused, the silicon wafer is placed into the HF solution to remove the formed PSG after the phosphorus diffusion.

6. And then, the silicon wafer is placed into a plasma enhanced chemical vapor deposition (PECVD) device for the double-sided SiNx coating protection. In the embodiment of the disclosure, a conventional SiNx coating process in the related art is used, and the disclosure does not improve the SiNx coating process.

7. Tests for the J₀ and the PL value are performed on the coated monitor wafer, which is sintered by a sintering furnace at a range of 700° C. to 850° C.

The above illustrates a preparation method of the monitor wafer based on the amorphous silicon integrated with the tunneling oxide layer process, and except for the preparation method for amorphous silicon integrated with the tunneling oxide layer of the disclosure, other treatment manner belong to conventional process methods in the related art.

A method for preparing a monitor wafer through a non-integrated process (as a comparison) is the same as the steps described above, and differences are as follows. In the step 3, the tunneling oxide layer and the amorphous silicon grow by using a conventional method, the silicon wafer is cooled after growing the tunneling oxide layer is completed, and then the amorphous silicon grows. In addition, the conventional process usually uses a normal-pressure oxidation process, and the normal-pressure oxidation is usually high in growth rate, poor in controllability, greatly affected by environment, and unfavorable for the ultra-thin tunneling oxide layer required for the tunneling oxide passivated contact (TOPCON) process. However, the disclosure maintains the certain vacuum degree of 100-700 Torr to reduce the growth rate of the oxide layer, and is less affected by environmental cleanliness, etc. under vacuum. Furthermore, the disclosure can obtain the thin oxide layer with a high quality, which is characterized by a significant improvement in passivation data. The conventional oxidation process is as follows: loading (i.e., oxidation furnace tube carrier)-inlet tube-heating-oxygen introduction for oxidation (under normal pressure)-cooling-outlet tube for cooling-unloading-wafer loading (i.e., amorphous silicon furnace tube carrier)-inlet tube-heating and vacuumizing-growing amorphous silicon-cooling and breaking vacuumizing-outlet tube for cooling again-unloading, which is relatively complex and needs to switch the carrier.

Table 1 and Table 2 illustrate passivation results of the monitor wafers prepared by the integrated process (i.e., according to the disclosure) and the non-integrated process (i.e., the conventional process), respectively.

Table 1 illustrates the passivation results of the amorphous silicon integrated with the oxide layer.

| | Life- | | | | |
|---|---|---|---|---|---|
| Position | time_(μs) | Jo_(fA/cm²) | I-Voc_(V) | I-FF_(%) | PL |
| 1 | 2314.57 | 11.96 | 0.7103 | 84.8 | 68894 |
| 2 | 2370.49 | 10.96 | 0.7104 | 85.16 | 69475 |
| 3 | 2720.07 | 11.58 | 0.7116 | 85.51 | 69362 |
| 4 | 2245.47 | 10.77 | 0.7111 | 84.26 | 70013 |
| 5 | 3315.86 | 10.08 | 0.7134 | 86.02 | 69740 |

Table 2 illustrates the passivation results of respectively preparing the oxide layer and the amorphous silicon layer.

| | Life- | | | | |
|---|---|---|---|---|---|
| Position | time_(μs) | Jo_(fA/cm²) | I-Voc_(V) | I-FF_(%) | PL |
| 1 | 732.24 | 32.08 | 0.6846 | 83.94 | 58585 |
| 2 | 1449.31 | 19.98 | 0.6983 | 84.96 | 70892 |
| 3 | 2124.98 | 14.17 | 0.7076 | 85.13 | 72199 |
| 4 | 869.78 | 29.46 | 0.6878 | 84.31 | 58662 |
| 5 | 800.79 | 33.79 | 0.6858 | 82.85 | 47286 |

Annotation: J₀ represents the saturation current density, Lifetime represents minority carrier lifetime, Voc represents an open circuit voltage (VOC), FF represents a fill factor (FF), and PL represents photoluminescence intensity, and when the photoluminescence intensity is higher, it is indicated that the passivation capability of the monitor wafer is stronger. Furthermore, position represents that during the test, the monitor wafer is uniformly distributed from an inlet of the furnace tube to an outlet of the furnace tube, and the distributed portion of the monitor wafer are numbered in sequence of 1-5, which is used to monitor the amorphous silicon growing of all of the areas within the furnace tube.

It can be seen from the Table 1 and the Table 2 that compared with the preparation method for amorphous silicon by using the non-integrated process, the sample (also referred to the monitor wafer) prepared by the method of the disclosure has a high minority carrier lifetime, a low current density value, a large filling factor, and a large open circuit voltage. Furthermore, the difference among the test data of the monitor wafer distributed at different positions within the furnace tube is small, which indicates that the sample prepared by the method of the disclosure has good uniformity.

The minority carrier lifetime of the sample prepared by the method of the disclosure can reach more than 2,000 microseconds (μs), which indicates that the sample has a good passivation performance. Furthermore, the minority carrier lifetime of the sample is higher, the recombination is weak, and the cell efficiency is higher. In summary, the passivation results of the amorphous silicon integrated with the oxide layer prepared by the disclosure are superior to those of the sample prepared by the oxidation and amorphous silicon growth with a separation mode.

It should be understood by those skilled in the related art that the technical features of the above embodiments can be combined arbitrarily. In order to make the description of the embodiments concise, the disclosure does not describe all of the possible combinations of the technical features in the foregoing embodiments. However, as long as there is no contradiction in the combination of these technical features, it should be considered that the scope of the disclosure is set forth.

The above embodiments only express several embodiments of the disclosure, and the description thereof is more specific and detailed, but cannot be understood as a limitation to the scope of the disclosure. It should be noted that, for those skilled in the related art, several variations and improvements can be made without departing from the concept of the disclosure, which all fall within the scope of the protection of the disclosure.

What is claimed is:

1. A preparation method for amorphous silicon integrated with a tunneling oxide layer, comprising the following steps:
step 1, boat loading, comprising: loading a silicon wafer subjected to surface polishing into a boat, pushing the boat into a furnace tube, and introducing nitrogen (N₂) during the boat loading; after the boat loading is completed, stopping introducing the N₂, and then vacuumizing the furnace tube, and keeping a vacuum degree of the furnace tube at a range of 100 Torricelli (Torr) to 700 Torr;
step 2, oxidation, comprising: keeping a pressure of the furnace tube stable, introducing oxygen (O₂) into the furnace tube after heating the furnace tube to a stable temperature, and then growing silicon oxide (SiO₂); wherein the stable temperature of the furnace tube in the step 2 is in a range of 550 degrees Celsius (° C.) to 620° C., a flow range of introducing the O₂ is in a range of 5 standard litter per minute (slm) to 30 slm, and a time of introducing the O₂ is in a range of 5 minutes (min) to 30 min;
step 3, vacuumizing, comprising: after the oxidation is completed, turning on a valve of the furnace tube to vacuumize to make the vacuum degree of the furnace tube below 1,000 milliTorr (mTorr);
step 4, pressurizing, comprising: introducing N₂ to improve the pressure of the furnace tube and maintaining the improved pressure for a period of time;
step 5, amorphous silicon growing, comprising: introducing silicon hydride (SiH₄) to grow the amorphous silicon under a stable temperature and a stable pressure; wherein the stable temperature in the step 5 is in a range of 550° C. to 600° C., a flow range of introducing the SiH₄ is in a range of 80 standard cubic centimeter per minute (sccm) to 1,000 sccm, the stable pressure in the step 5 is in a range of 250 mTorr to 600 mTorr, and a time of introducing the SiH₄ is in a range of 10 min to 150 min;
step 6, introducing N₂ into the furnace tube and discharging residual SiH₄ in the furnace tube;
step 7, cooling and boat unloading, comprising: breaking the vacuumizing and removing the boat from the furnace tube after the temperature of the furnace tube is cooled; and
step 8, wafer unloading, comprising: removing the silicon wafer from the boat.

2. The preparation method for amorphous silicon integrated with the tunneling oxide layer as claimed in claim 1, wherein in the step 1, an internal temperature of the furnace tube is in a range of 450° C. to 600° C., and a flow range of introducing the N₂ is in a range of 1 slm to 30 slm.

3. The preparation method for amorphous silicon integrated with the tunneling oxide layer as claimed in claim 1, wherein in the step 2, the stable temperature of the furnace tube is in a range of 560° C. to 600° C.

4. The preparation method for amorphous silicon integrated with the tunneling oxide layer as claimed in claim 1, wherein in the step 2, the flow range of introducing the O₂ is in a range of 10 slm to 20 slm, and the time of introducing the O₂ is in a range of 8 min to 15 min.

5. The preparation method for amorphous silicon integrated with the tunneling oxide layer as claimed in claim 1, wherein the step 3 comprises: making the vacuum degree of the furnace tube less than 100 mTorr by the vacuumizing.

6. The preparation method for amorphous silicon integrated with the tunneling oxide layer as claimed in claim 1, wherein in the step 4, a flow range of introducing the N₂ is in a range of 100 sccm to 10,000 sccm, the improved pressure is in a range of 250 mTorr to 1,000 mTorr, and the period of time is in a range of 0.5 min to 10 min.

7. The preparation method for amorphous silicon integrated with the tunneling oxide layer as claimed in claim 1, wherein in the step 4, a flow range of introducing the N₂ is in a range of 200 sccm to 1,000 sccm, the improved pressure is in a range of 250 mTorr to 600 mTorr, and the period of time is in a range of 0.5 min to 5 min.

8. The preparation method for amorphous silicon integrated with the tunneling oxide layer as claimed in claim 1, wherein in the step 5, the flow range of introducing the SiH₄ is in a range of 200 sccm to 500 sccm, the stable pressure is in a range of 300 mTorr to 500 mTorr, and the time of introducing the SiH₄ is in a range of 20 min to 60 min.

9. The preparation method for amorphous silicon integrated with the tunneling oxide layer as claimed in claim 1, wherein in the step 7, the temperature of the furnace tube is cooled to a range of 400° C. to 550° C.
